(19) United States
(12) Patent Application Publication
(10) Pub. No.: US 2014/0224313 A1
(43) Pub. Date: Aug. 14, 2014

(54) SILICON SOLAR CELL STRUCTURE

(71) Applicant: Industrial Technology Research Institute, Hsinchu (TW)

(72) Inventors: Der-Chin Wu, Tainan City (TW); Li-Yu Li, Taipei City (TW); Chen-Hsun Du, Taipei City (TW); Bing-Cyun Chen, New Taipei City (TW)

(21) Appl. No.: 13/939,185

(22) Filed: Jul. 11, 2013

(30) Foreign Application Priority Data
Feb. 8, 2013 (TW) 102105163

(51) Int. Cl. H01L 31/0216

(52) U.S. Cl. CPC H01L 31/02167
USPC 136/256

(57) ABSTRACT

A silicon solar cell structure includes a silicon substrate, a phosphorus diffusion doping layer within a surface of the silicon substrate, a passivation layer on the surface of the silicon substrate, a phosphorous-containing oxide layer between the passivation layer and the phosphorus diffusion doping layer within the silicon substrate, and an electrode on the surface of the silicon substrate through the passivation layer and the phosphorous-containing oxide layer.

### CROSS-REFERENCE TO RELATED APPLICATION

This application claims the priority benefit of Taiwan application serial no. 102105163, filed on Feb. 8, 2013. The entirety of the above-mentioned patent application is hereby incorporated by reference herein and made a part of this specification.

### TECHNICAL FIELD

The disclosure relates to a silicon solar cell structure.

### BACKGROUND

In recent years, the global climate and temperature become anomalistic due to environmental pollution. Therefore, demands on sustainable and clean energies rapidly draw much attention from countries around the world. The solar energy is no doubt the major supply among carbon-free energies, and a solar cell is a type of photoelectric conversion device capable of directly converting the solar energy into electricity. According to a report from EPIA about market shares of the global solar cells, crystalline silicon solar cells take the greatest share.

A conventional manufacturing method of a silicon solar cell at least includes texturizing a monocrystalline silicon wafer, cleaning the surface of the wafer, performing a phosphorous diffusion process, depositing a P₂O₅ layer on the surface of the wafer to form a phosphorous-containing oxide layer (which includes the P₂O₅ layer and a SiO₂:P layer), etching a rear surface, removing the phosphorous-containing oxide layer since the P₂O₅ layer therein is conventionally regarded as recombination centers, which causes a great damage to surface passivation of the wafer. Thus, the phosphorous-containing oxide layer is removed generally by using a liquid contain hydrogen fluoride. Afterwards, a PECVD SiNx anti-reflection film is coated, an electrode manufacturing process is performed. These manufacturing processes have been the standard procedures of current cell manufacturers and hard to be replaced. However, if the manufacturing processes may be simplified without affecting the cell efficiency, it will be a great progress of the crystalline silicon solar cell.

### SUMMARY

One of exemplary embodiments comprises a silicon solar cell structure. The silicon solar cell structure includes a silicon substrate, a phosphorus diffusion doping layer within a surface of the silicon substrate, a passivation layer on the surface of the silicon substrate, a phosphorous-containing oxide layer between the passivation layer and the phosphorus diffusion doping layer within the silicon substrate, and an electrode on the surface of the silicon substrate and passing through the passivation layer and the phosphorous-containing oxide layer, such that the electrode contacts with the phosphorus diffusion doping layer within the silicon substrate.

Another exemplary embodiment comprises a silicon solar cell structure. The silicon solar cell structure includes a silicon substrate, an anti-reflection layer on a front surface of the silicon substrate, a phosphorous-containing oxide layer between the anti-reflection layer and the front surface of the silicon substrate, a first contact and a second contact. The silicon substrate has a front-side field (FSF) layer in the front surface, and the silicon substrate has a back-side field (BSF) and an emitter layer separately in a rear surface of the silicon substrate. The first contact is on the rear surface of the silicon substrate and contacts the emitter layer, and the second contact is on the rear surface of the silicon substrate and contacts the BSF layer.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a cross-sectional schematic diagram illustrating a silicon solar cell structure according to a first embodiment of the disclosure.

FIG. 2 is a partial enlarged diagram of FIG. 1.

FIG. 3 is a cross-sectional schematic diagram illustrating a silicon solar cell structure according to a second embodiment of the disclosure.

FIG. 4 is a cross-sectional schematic diagram illustrating a silicon solar cell structure according to a third embodiment of the disclosure.

FIG. 5 is a cross-sectional schematic diagram illustrating a silicon solar cell structure according to a fourth embodiment of the disclosure.

FIG. 6 is a graph showing curves illustrating relationships between thickness changes of silicon nitride and current density for the solar cell structure of Experiment 1.

FIG. 7 is a graph showing curves illustrating relationships between thickness changes of silicon nitride and current density for the solar cell structure of Experiment 1.

FIG. 8A and FIG. 8B are schematic diagrams respectively illustrating samples of Experiment 2.

FIG. 9 is a graph showing a curve illustrating a relationship between temperatures of a diffusion process and minority-carrier lifetimes of Experiment 2.

### DETAILED DESCRIPTION OF DISCLOSED EMBODIMENTS

The following description is supplemented by accompanying drawings to be illustrated more fully. However, the disclosure may be implemented in multiple different manners and is not limited to the embodiments described herein. For the sake for clarity, sizes and relative sizes of each layer and each region shown in the drawings may be exaggerated.

Hereinafter, when an element or layer is referred to as being “located on” another element or layer, it can be directly located on the other element or layer. That is, for example, intervening elements or layers may be present. Moreover, when an element is referred to as “contacting” another element or layer, there are no intervening elements or layers present therebetween. Other words for describing space relations, such as “below”, “above” or the like are used to describe the relationship between an element or layer and another element or layer. Such spatially relative terms are used to describe a relationship between an element or layer and another element or layer illustrated in the drawings. It will be understood that the spatially relative terms are intended to encompass different orientations of the elements in use and/or operation in addition to the orientation depicted in the drawings. For example, if the device in the drawings is turned over, elements described as “on” and/or “above” other elements or layers would then be oriented “below” and/or “beneath” the other elements or layers.

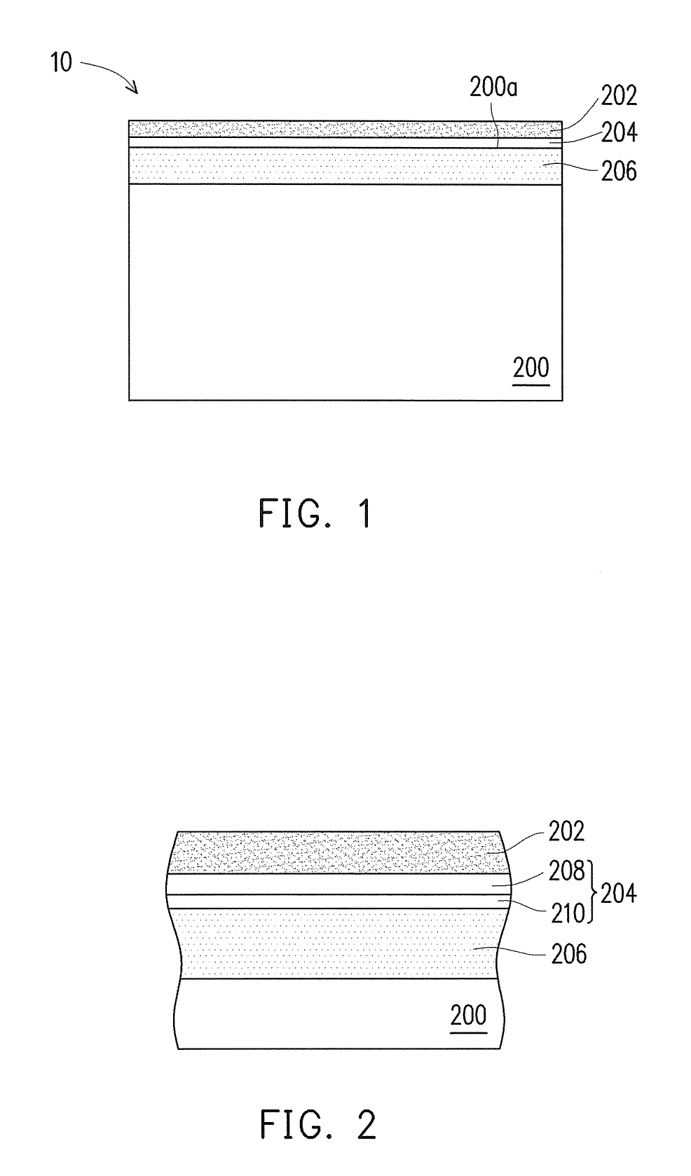

FIG. 1 is a cross-sectional schematic diagram illustrating a silicon solar cell structure according to a first embodiment of the disclosure.

With reference to FIG. 1, a silicon solar cell structure 10 includes a silicon substrate 200, a passivation layer 202 on a surface 200a of the silicon substrate 200 and a phosphorous-containing oxide layer 204 between the surface 200a of the silicon substrate 200 and the passivation layer 202. The silicon substrate 200 is, for example, a P-type silicon, and a phosphorus diffusion doping layer 206 serving as an emitter layer is doped within the surface 200a thereof. If the surface 200a is a front surface of the silicon solar cell structure 10, the passivation layer 202 may serve as an anti-reflection layer. The passivation layer 202 is, for example, a silicon nitride layer, a SiO₂ layer, a TiO₂ layer, an MgF₂ layer or a combination thereof, and a total thickness of the phosphorous-containing oxide layer 204 and the passivation layer 202 is between 50 nm and 200 nm. A thickness of the phosphorous-containing oxide layer 204 is, for example, between 5 nm and 40 nm, and preferably under 30 nm to more particularly facilitate in optical performance. Additionally, the surface 200a of the silicon substrate 200 is planar as shown in FIG. 1, and alternatively, it may be a textured surface to reduce light reflection.

The phosphorous-containing oxide layer 204 is formed by a conventional high-temperature phosphorous diffusion process and may include a P₂O₅ layer 208 contacting with the passivation layer 202 and a SiO₂:P layer 210 contacting with the surface 200a of the silicon substrate 200. Referring to FIG. 2, it is a partial enlarged diagram of FIG. 1. The SiO₂:P layer 210 is between the P₂O₅ layer 208 and the phosphorus diffusion doping layer 206, and thus, the phosphorous-containing oxide layer 204 of the present embodiment may have a good passivation effect about reducing carrier recombination at the surface 200a, which may be expected to facilitate in passivating the phosphorous-containing oxide layer 204 by increasing a thickness of the SiO₂:P layer 210.

In conventional solar cell manufacturing process, the phosphorus diffusion doping layer 206 depicted in FIG. 1 is formed after the phosphorous diffusion process, the phosphorous-containing oxide layer 204 on the surface 200a of the silicon substrate 200 is removed before the anti-reflection layer (or the passivation layer 202) is performed. Comparing with the conventional manufacturing process, the phosphorous-containing oxide layer 204 of the present embodiment is not necessary to be removed. It is expected the cell efficiencies can increase and the process is simplified for cost-down.

In addition, if the silicon substrate 200 is a N-type silicon substrate, the surface 200a of the silicon substrate 200 may be a rear surface of the silicon solar cell structure 10. When the phosphorous-containing oxide layer 204 is disposed on the rear surface of the silicon solar cell structure 10, it may also provide passivation of the rear surface of the silicon solar cell structure 10, whereby reducing the junction resistance between an electrode (not shown) and the silicon substrate 200 after high-temperature firing process to improve cell efficiency.

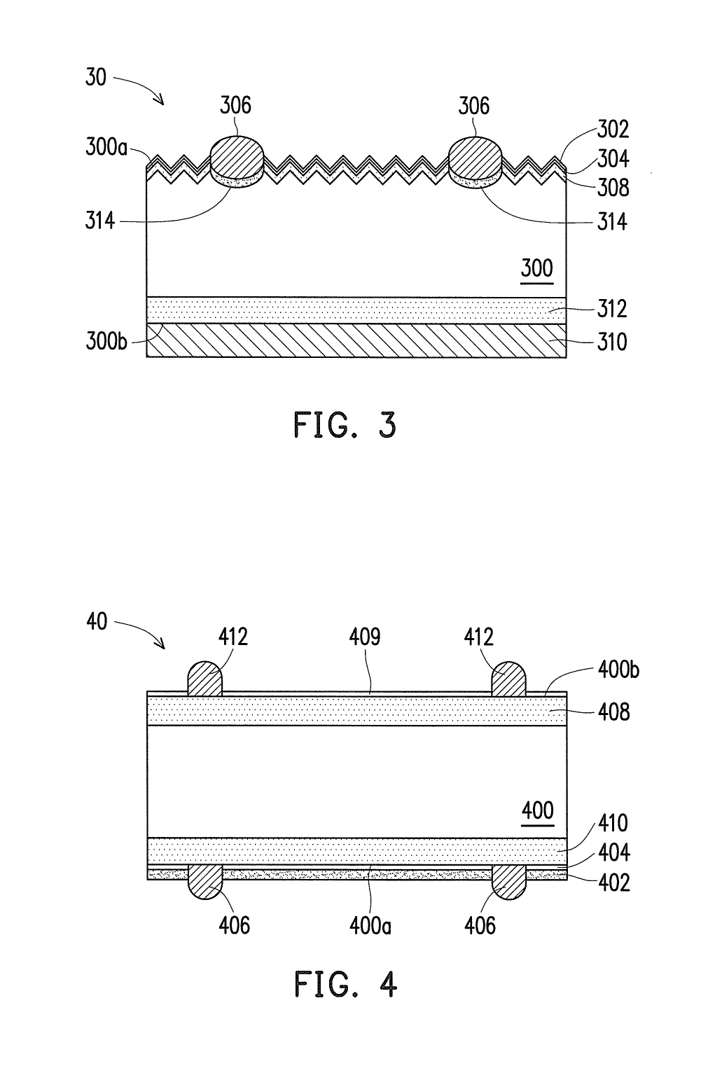

FIG. 3 is a cross-sectional schematic diagram illustrating a silicon solar cell structure according to a second embodiment of the disclosure.

With reference to FIG. 3, a silicon solar cell structure 30 includes a silicon substrate 300, an anti-reflection layer 302 on a front surface 300a of the silicon substrate 300, a phosphorous-containing oxide layer 304 between the front surface 300a and the anti-reflection layer 302 and several front electrodes 306. The silicon substrate 300 is, for example, is a P-type silicon having a phosphorus diffusion doping layer 308 serving as an emitter doped in the front surface 300a thereof. The front electrode 306 is on the front surface 300a of the silicon substrate 300 and passes through the anti-reflection layer 302 and the phosphorous-containing oxide layer 304 to contact the phosphorus diffusion doping layer 308 in the silicon substrate 300. The phosphorous-containing oxide layer 304 includes, for example, a P₂O₅ layer contacting the anti-reflection layer 302 and a SiO₂:P layer contacting the front surface 300a of the silicon substrate 300, which is similar to FIG. 2.

Since the phosphorous-containing oxide layer 304 is disposed on the front surface 300a of the silicon substrate 300, taking into consideration the optical performance, a total thickness of the phosphorous-containing oxide layer 304 and the anti-reflection layer 302 is, for example, between 50 nm and 200 nm, and a thickness of the phosphorous-containing oxide layer 304 is between 5 nm and 40 nm. Moreover, in the present embodiment, the front surface 300a of the silicon substrate 300 is a textured surface, and thus the light reflection may be reduced. Further, the silicon solar cell structure 30 may also include a back electrode 310 on the rear surface 300b of the silicon substrate 300. Meanwhile, a p+ region 312 serving as a back-side field (BSF) layer may be disposed on the rear surface 300b of the silicon substrate 300.

Besides, when the front electrode 306 of the silicon solar cell structure 30 is formed by silver paste or electroplating, the phosphorous in the phosphorous-containing oxide layer 304 is melted at high temperature and doped into the silicon substrate 300, such that a heavily doped region 314 is formed beneath the front electrode 306, which facilitates in reducing a junction resistance value of a metal-semiconductor junction so as to improve conversion efficiency. To be specific, when the front electrode 306 is formed by silver paste, since the silver paste contains glass, the anti-reflection layer 302 may be partly etched by the glass at high temperature up to 800-900° C., and the phosphorous in the phosphorous-containing oxide layer 304 is melted to form a n-type heavily doped region 314 at the metal-semiconductor junction (in the silicon substrate 300), and thus the junction resistance is reduced. Likewise, in the step of forming the front electrode 306 by electroplating, if the anti-reflection layer 302 is removed by laser in advance, the phosphorous-containing oxide layer 304 is also removed and re-melted due to the high energy laser. Thereby, the heavily doped region 314 may also be formed in the silicon substrate 300. Thereafter, the front electrode 306 is formed on the region processed by the laser through the electroplating process or the like.

FIG. 4 is a cross-sectional schematic diagram illustrating a silicon solar cell structure according to a third embodiment of the disclosure.

With reference to FIG. 4, a silicon solar cell structure 40 includes a silicon substrate 400, a passivation layer 402 on the rear surface 400a of the silicon substrate 400, a phosphorous-containing oxide layer 404, between the rear surface 400a and the passivation layer 402 and several back electrodes 406. The silicon substrate 400 is, for example, a N-type silicon having a p+ region serving as a front emitter 408 doped in the front surface 400b, and a phosphorus diffusion doping layer 410 is disposed on the rear surface 400a of the silicon substrate 400. The back electrode 406 is located on the rear surface 400a of the silicon substrate 400 and passes through the passivation layer 402 and the phosphorous-containing oxide layer 404 to contact the phosphorus diffusion doping layer 410 in the silicon substrate 400. The phosphorous-containing oxide layer 404 may refer to the description in regard to the FIG. 2 and will no longer repeated. The front surface 400b has an anti-reflection layer (also serving as a passivation layer) 409 on the front emitter 408 and has front electrodes 412.

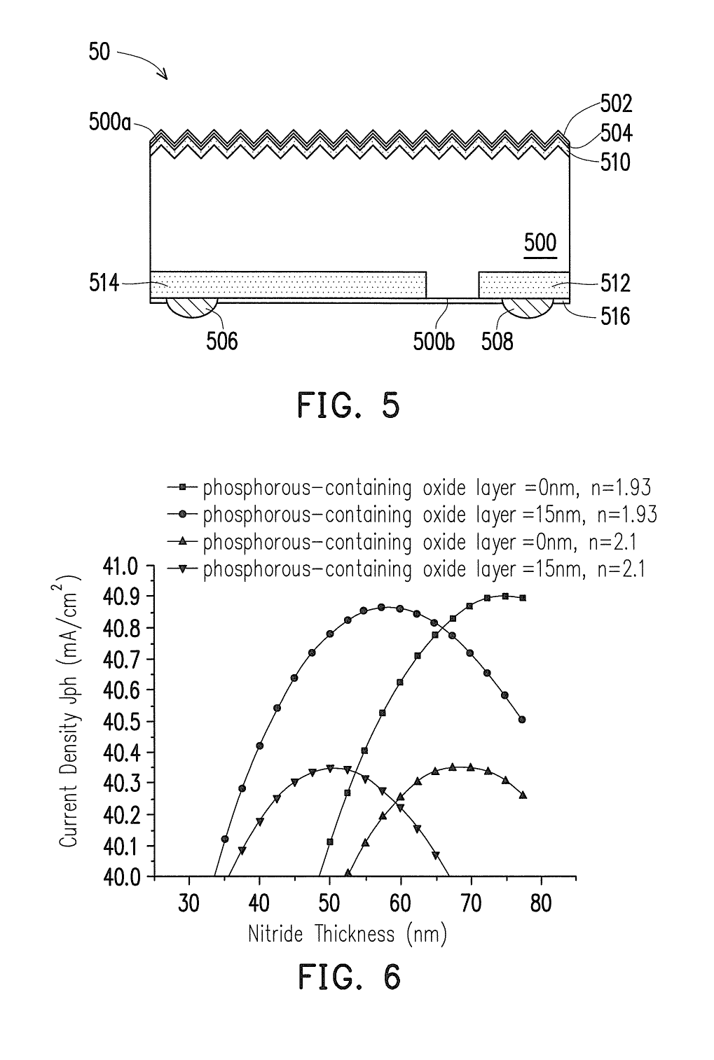

FIG. 5 is a cross-sectional schematic diagram illustrating a silicon solar cell structure according to a fourth embodiment of the disclosure.

With reference to FIG. 5, a silicon solar cell structure 50 includes a silicon substrate 500, an anti-reflection layer 502 on a front surface 500a of the silicon substrate 500, a phosphorous-containing oxide layer 504 between the front surface 500a of the silicon substrate 500 and the anti-reflection layer 502, a first contact 506 and a second contact 508. The silicon substrate 500 has a front-side field (FSF) layer 510 in the front surface 500a, and the silicon substrate 500 has a BSF layer 512 and an emitter layer 514 in a rear surface 500b thereof. The BSF layer 512 and the emitter layer 514 are separate from each other. Both the first contact 506 and the second contact 508 are located on the rear surface 500b of the silicon substrate 500. The first contact 506 contacts the emitter layer 514, and the second contact 508 contacts the BSF layer 512. The silicon solar cell structure 50 of the fourth embodiment may be a interdigitated back electrode (IBC) solar cell, and accordingly the silicon substrate 500 is a n-type silicon, the FSF layer 510 is a n+ FSF, the BSF layer 512 is an n++ BSF, and the emitter layer 514 is a p++ region.

The phosphorous-containing oxide layer 504 of the fourth embodiment includes, for example, a P₂O₅ layer contacting with the anti-reflection layer 502 and a SiO₂:P contacting with the front surface 500a of the silicon substrate 500, which is similar to FIG. 2. The phosphorous-containing oxide layer 504 is on the front surface 500a of the silicon substrate 500, and thus, taking into consideration the optical performance, a total thickness of the phosphorous-containing oxide layer 504 and the anti-reflection layer 502 is, for example, between 50 nm and 200 mm, and a thickness of the phosphorous-containing oxide layer 504 is between 5 nm and 40 nm. Moreover, the front surface 500a of the silicon substrate 500 of the present embodiment is a textured surface for reducing light reflection. Further, the rear surface 500b of the silicon substrate 500 may be covered by a passivation layer 516, for example, a silicon nitride layer or a silicon oxide layer.

A plurality of experiments is illustrated hereinafter to describe the disclosure in detail.

Experiment 1: relation of a phosphorous-containing oxide layer and a SiNx thin film.

In conventional silicon solar cell structure, a silicon nitride (SiNx:H) thin film having a thickness of 600 nm and a refraction index within a range of 2-2.1 is usually used as a passivation layer because the range of the refraction index is good for passivation. Generally, an anti-reflection layer with the optimal optical performance should have a refraction index around 1.9, but it is low on hydrogen content, which results in bad passivation effect. Accordingly, in the conventional process, the refraction index is gradually increased up to 2-2.1 to increase the hydrogen content of the SiNx:H thin film. As such, a few optical properties are sacrificed to exchange for the passivation effect so as to obtain better efficiency.

However, in Experiment 1, the optical property between the phosphorous-containing oxide layer and the silicon substrate is considered to reduce an optical reflection effect of the phosphorous-containing oxide layer and the silicon substrate and get better photocurrents so as to improve the cell efficiency. The influence of different SiNx:H thin films obtained from an optical simulation and different thickness of the phosphorous-containing oxide layer on the photocurrents is illustrated in FIG. 6.

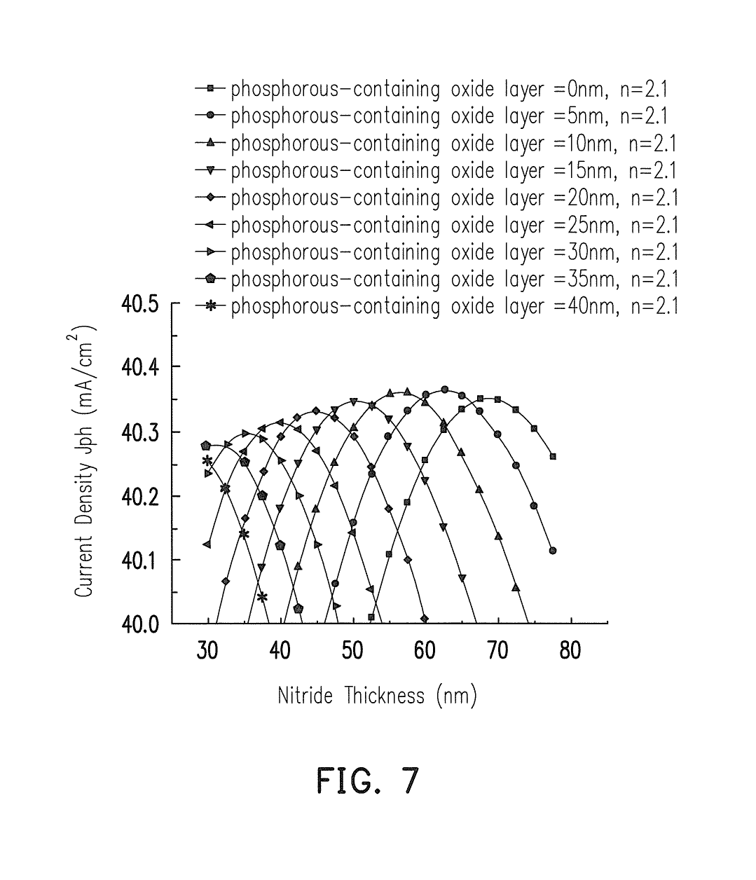

In FIG. 7, an optical simulation for different thickness of the SiNx thin film are performed under an assumption that an anti-reflection layer is a SiNx layer having a refraction index of 2.1, a phosphorous-containing oxide layer has a refraction index of 1.6, and a silicon substrate has a refraction index of 3.6. Moreover, this optical simulation is performed by using the thickness of the phosphorous-containing oxide layer as variables, and its result is shown in FIG. 7.

Referring to FIG. 7, when the thickness of the phosphorous-containing oxide layer is under 10 nm, the photocurrent density is higher than that in case of no phosphorous-containing oxide layer. Moreover, when the thickness of the phosphorous-containing oxide layer is up to 40 nm, the difference of photocurrent density between with and without phosphorous-containing oxide layer is less than 0.1 mA/cm². In other words, only if the thickness of the SiNx thin film is adaptively adjusted, whether the phosphorous-containing oxide layer exists (i.e., <40 nm) has very little optical influence on the cell efficiency. Referring to data shown in FIG. 7, the less the thickness of the phosphorous-containing oxide layer is, the more the photocurrents is obtained.

According to FIG. 6, when the SiNx thin film with lower refraction index is applied, the current density may be improved, and the difference may be up to 0.7 mA/cm². In other words, the difference of the cell conversion efficiency may reach up to 0.3%. Accordingly, it is successful to apply the SiNx thin film with low refraction index by the adjustment of the thickness of the phosphorous-containing oxide layer and the passivation property for the phosphorous diffusion.

Experiment 2: the passivation property of the phosphorous-containing oxide layer.

When the conditions for the phosphorous diffusion are adjusted, it is found that during diffusion, the passivation property is significantly improved with the thickness decrease of the phosphorous-containing oxide layer and the increase of oxygen flow rate. That is, if a SiO₂:P layer with few nanometers is formed on a junction between the phosphorous-containing oxide layer and the silicon, the passivation property will be improved.

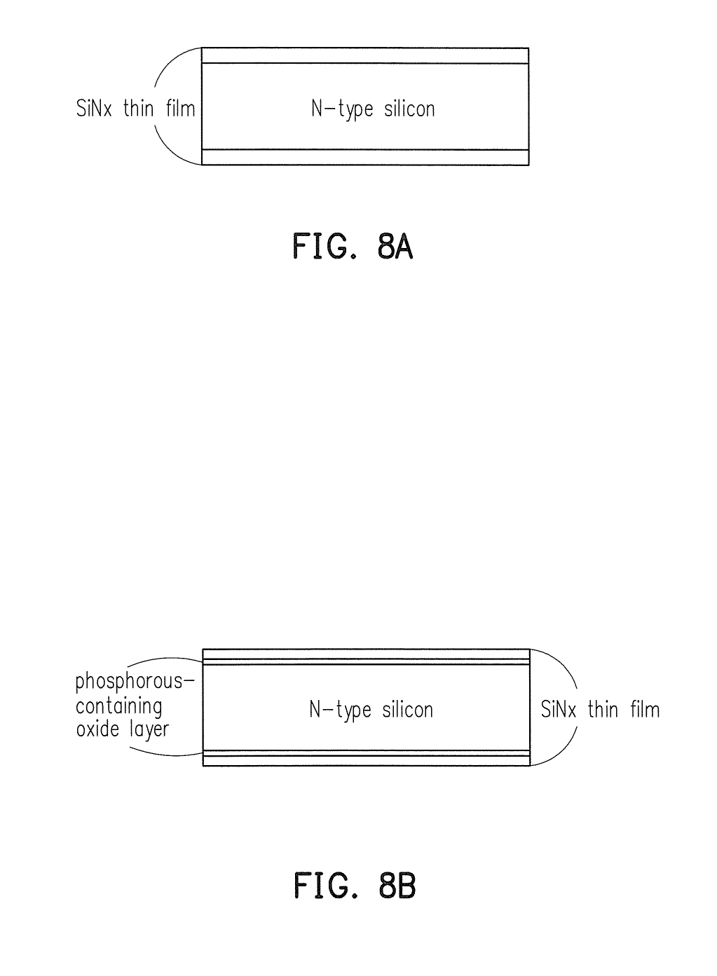

Accordingly, in this case, silicon solar cell structures illustrated in FIG. 8A and FIG. 8B are respectively manufactured and tested by a minority-carrier lifetime tester. After the phosphorous diffusion and double-sided silicon nitride passivation layer coating are performed on a N-type wafer, a sample of a phosphorous-containing oxide layer (as shown in FIG. 8B) has a minority-carrier lifetime >1000 μs, and a sample with the phosphorous-containing oxide layer removed and coated with silicon nitride (as shown in FIG. 8A) has a minority-carrier lifetime up to 500 μs. Accordingly, the structure having the phosphorous-containing oxide layer may still have high minority-carrier lifetime property.

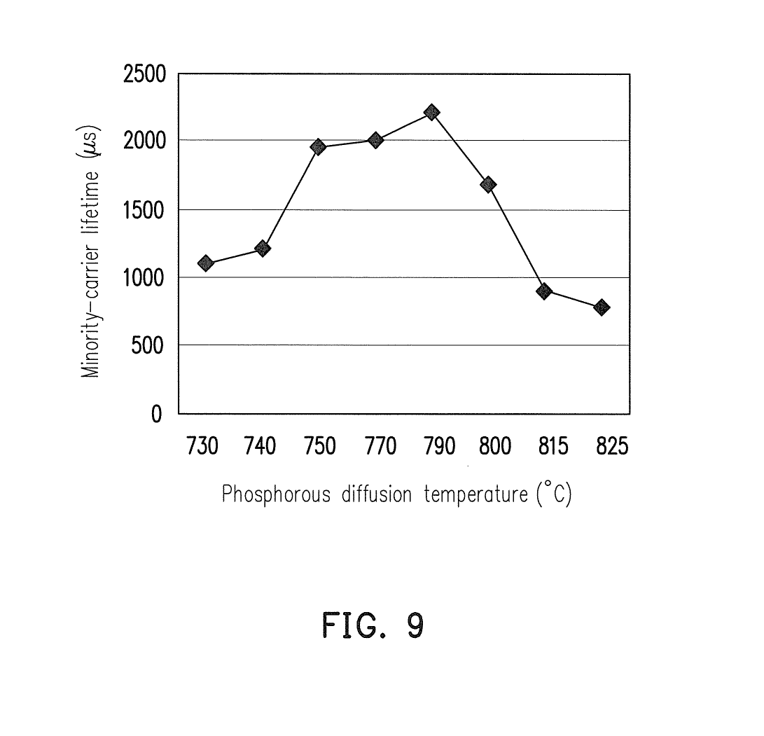

Furthermore, it is expected that by adjusting the temperature for the diffusion process, the thickness of the phosphorous-containing oxide layer may become thicker, and then a high-quality oxide layer is formed. In FIG. 9, several process temperatures for the phosphorous diffusion are compared, where the phosphorous-containing oxide layer is retained, and the silicon nitride layer are coated on both surfaces to manufacture the structure of FIG. 8B. A result of a very high carrier lifetime may be obtained by the test using the minority-carrier lifetime tester. A high carrier lifetime represents a good passivation layer. According to FIG. 9, it can be explained that the phosphorous-containing oxide layer may serve as a good passivation layer, of which the passivation effect is even better than the silicon nitride passivation layer.

When comparing the conversion efficiencies of solar cells with and without the phosphorous-containing oxide layer, a resistance value of an emitter for the phosphorous diffusion is set at 100 ohm/□, the front surface and the back electrode structures are manufactured by a screen printing process with a high-temperature firing process. The experimental group keeps the P₂O₅ layer structure without removing the phosphorous-containing oxide layer, while the control group utilizes the conventional process with removing the phosphorous-containing oxide layer. Results of the two groups are shown in Table 1 as follows.

TABLE 1

| Resistance | | | | | | |
|---|---|---|---|---|---|---|
| Value | | | J_{SC} | | F.F. | Cell eff. |
| (Ω/□) | Condition | I_{SC} [A] | [mA/cm²] | V_{OC} [V] | [%] | [%] |
| 100 | With P₂O₅ | 5.93 | 38.03 | 0.646 | 77.88 | 19.13 |
| 100 | Without | 5.93 | 38.02 | 0.643 | 75.41 | 18.44 |
| | P₂O₅ | | | | | |

With reference to Table 1, comparing the experimental group with the control group, when the samples have the same short-circuit current (I_{SC}), the open-circuit voltages (V_{OC}) of the sample with P₂O₅ are relatively higher than that without P₂O₅. That is to say, the phosphorous-containing oxide layer causes no negative influence on the samples. Meanwhile, it is found from Table 1 that among the samples having a high emitter resistance value (100Ω/□), the resistance of the metal-semiconductor junction of the sample with P₂O₅ is obviously lowered down, such that the fill factor (F.F.) has a higher value. Accordingly, when a sample having a higher emitter resistance value is used for comparison, it can be seen that the sample having the phosphorous-containing oxide layer achieves outstanding property, of which results are shown in Table 2 as follows.

TABLE 2

| | J_{SC} | | | Cell eff. | Parallel | Serial |
|---|---|---|---|---|---|---|
| Condition | [mA/cm²] | V_{OC} [V] | F.F. [%] | [%] | resistance [Ω] | resistance [Ω] |
| With P₂O₅ | 38.19 | 0.632 | 64.73 | 15.63 | 8.50 | 0.0135 |
| Without | 38.09 | 0.601 | 22.07 | 5.05 | 9.59 | 0.1133 |
| P₂O₅ | | | | | | |

With reference to the results shown in Table 2, if the phosphorous-containing oxide layer is removed from the sample having a high emitter resistance value (131Ω/□), the sample will have a greater junction resistance after high-temperature firing, such that the F.F. is drop down to only 22. In contrast, in the sample with P₂O₅, the F.F. is about 64. That is to say, the phosphorous-containing oxide layer facilitates in reducing the junction resistance after the firing process to improve the cell efficiency. According to the results from the two experiments (as shown in Table 1 and Table 2), it is highly proved that the existence of the phosphorous-containing oxide not only simplifies the process steps and reduces the production cost, but further improves the conversion efficiency of the solar cell.

Experiment 3: the phosphorous-containing oxide layer is applied in an experiment of an electroplating electrode.

When manufacturing the electroplating electrode, a laser drilling process is applied on a sample having a manufactured P-N junction and an anti-reflection layer to manufacture a fine-linewidth electroplating electrode. Thus, after the phosphorous diffusion process, the silicon nitride anti-reflection layer is plated. Then, two experimental groups are compared. One of the groups is a sample having the phosphorous-containing oxide layer structure, while the other is a sample with the phosphorous-containing oxide layer structure removed. The places cut open by the laser are then measured after the laser drilling process, and a sheet resistance of the sample with P₂O₅ is 47Ω/□, and a sheet resistance of the sample without P₂O₅ is 117Ω/□. Namely, the existence of the phosphorous-containing oxide layer, after the laser drilling process, makes it being re-melted with the emitter semiconductor layer due to high-temperature laser, which results in a heavily doped region. Accordingly, according to the experimental measurement, it is found that the sheet resistance has a downward trend, such that a specific selective emitter structure. Due to heavy doping, the junction resistance of the metal-semiconductor junction may be reduced, and thus the experimental on the electroplating electrode is further performed, of which results are shown in Table 3 as follows.

TABLE 3

| | | J_{SC} | V_{OC} | | Cell eff. | Rₛₑᵣ |
|---|---|---|---|---|---|---|
| Condition | I_{SC} [A] | [mA/cm²] | [V] | F.F. [%] | [%] | [ohm] |
| With P₂O₅ | 5.946 | 38.118 | 0.638 | 78.066 | 18.984 | 0.003 |
| Without | 5.934 | 38.038 | 0.637 | 77.217 | 18.706 | 0.004 |
| P₂O₅ | | | | | | |

To compare the conversion efficiencies of the solar cell with and without the phosphorous-containing oxide layer, the resistance value of the emitter formed by the phosphorous diffusion is set as 100 ohm/□, the back electrode structures are manufactured by the screen printing process with high-temperature firing process, and the front electrode structures are manufactured by laser scribing process and then electroplating a nickel-copper. In the experimental group, the phosphorous-containing oxide layer is not removed, and the P₂O₅ structure is retained. The control group applies the conventional process, where the phosphorous-containing oxide layer is removed. According to the results shown in Table 3, in the sample having the phosphorous-containing oxide layer, the short-circuit current and the open-circuit voltage are slightly greater than those in the sample with the phosphorous-containing oxide layer removed. However, the F.F. in the experimental group is unexpectedly increased. It is proved that the phosphorous-containing oxide layer may facilitate in reducing the junction resistance after the laser drilling and the electroplating processes so as to improve the cell efficiency.

Based on the above, in the silicon solar cell having the phosphorous-containing oxide layer structure introduced by the disclosure, the cell efficiency is not reduced but even increased and the production cost is reduced. According the aforementioned experiments, some facts are proved. First, in the samples having the phosphorous-containing oxide layer, the manufacturing process of the anti-reflection layer performed with the adaptive anti-reflection conditions does not result in reduction of the photocurrents. Moreover, the photocurrents may be increases by using the silicon nitride layer having a low refraction index. Second, it is also proved that the phosphorous-containing oxide layer does not lead to the reduction of the passivation property, and according to the experiments, the passivation effect of the phosphorous-containing oxide layer is even better than silicon nitride. Therein, in conventional silicon solar cell manufactured by screen printing and firing the electrode, if the phosphorous-containing oxide layer is not removed, the junction resistance between the metal electrode and the silicon may be effectively reduced so as to enhance the cell efficiency. Lastly, as for the silicon solar cell manufactured by laser drilling and electrode-plating, it is proved that after laser drilling, the selective emitter structure may formed on the cell having the phosphorous-containing oxide layer to reduce the junction resistance of the electroplating electrode and the semiconductor junction so as to improve the cell efficiency. The silicon solar cell structure with the phosphorous-containing oxide layer according to the disclosure has high passivation property, and it can be applied on the IBC solar cells in the future. The structure introduced by the disclosure may even actually and easily applied into the current mass production and has been proved to indeed facilitate in improving the cell efficiency according to the experiments.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A silicon solar cell structure, comprising:
a silicon substrate;
a phosphorus diffusion doping layer located within a surface of the silicon substrate;
a passivation layer, located on the surface of the silicon substrate;
a phosphorous-containing oxide layer, located between the passivation layer and the phosphorus diffusion doping layer within the silicon substrate; and
an electrode, located on the surface of the silicon substrate and passing through the passivation layer and the phosphorous-containing oxide layer, such that the electrode contacts with the phosphorus diffusion doping layer within the silicon substrate.

2. The silicon solar cell structure according to claim 1, wherein the phosphorous-containing oxide layer comprises:
a P₂O₅ layer, contacting the passivation layer; and
a SiO₂:P layer, contacting the phosphorus diffusion doping layer within the silicon substrate.

3. The silicon solar cell structure according to claim 1, wherein a total thickness of the phosphorous-containing oxide layer and the passivation layer is between 50 nm and 200 nm.

4. The silicon solar cell structure according to claim 1, wherein a thickness of the phosphorous-containing oxide layer is between 5 nm and 40 nm.

5. The silicon solar cell structure according to claim 1, wherein the silicon substrate is a P-type substrate and the surface is a front surface of the silicon substrate, the electrode is a front electrode, and the passivation layer also serves as an anti-reflection layer.

6. The silicon solar cell structure according to claim 5, further comprising:
a back electrode, located on a rear surface of the silicon substrate.

7. The silicon solar cell structure according to claim 1, wherein the silicon substrate is an N-type substrate, and the surface is a rear surface of the silicon substrate, and the electrode is a back electrode.

8. The silicon solar cell structure according to claim 7, further comprising:
an anti-reflection layer, located on a front surface of the silicon substrate;
a front emitter, located within the front surface of the silicon substrate; and
a front electrode, located on the front surface of the silicon substrate and passing through the anti-reflection layer to contact the front emitter.

9. A silicon solar cell structure, comprising:
a silicon substrate, having a front surface and a rear surface, wherein the silicon substrate has a front-side field (FSF) layer in the front surface, and has a back-side field (BSF) and an emitter layer separately in the rear surface;
an anti-reflection layer, located on the front surface of the silicon substrate;
a phosphorous-containing oxide layer, located between the anti-reflection layer and the front surface of the silicon substrate;
a first contact, located on the rear surface of the silicon substrate and contacting the emitter layer; and
a second contact, located on the rear surface of the silicon substrate and contacting the BSF layer.

10. The silicon solar cell structure according to claim 9, wherein the phosphorous-containing oxide layer comprises:
a P₂O₅ layer, contacting the anti-reflection layer; and
a SiO₂:P layer, contacting the front surface of the silicon substrate.

11. The silicon solar cell structure according to claim 9, wherein a total thickness of the phosphorous-containing oxide layer and the anti-reflection layer is between 50 nm and 200 nm.

12. The silicon solar cell structure according to claim 9, wherein a thickness of the phosphorous-containing oxide layer is between 5 nm and 40 nm.

13. The silicon solar cell structure according to claim 9, wherein the front surface of the silicon substrate is a textured surface.

14. The silicon solar cell structure according to claim 9, further comprising a passivation layer, covering the rear surface of the silicon substrate.

15. The silicon solar cell structure according to claim 14, wherein the passivation layer is a silicon nitride layer, a SiO₂ layer, a TiO₂ layer, an MgF₂ layer or a combination thereof.
